(19) United States
(12) Patent Application Publication
(10) Pub. No.: US 2010/0213508 A1
(43) Pub. Date: Aug. 26, 2010

(54) SEMICONDUCTOR DEVICE

(75) Inventor: Hiroto YAMAGIWA, Hyogo (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/636,153

(22) Filed: Dec. 11, 2009

(30) Foreign Application Priority Data
Feb. 20, 2009 (JP) 2009-038162

(51) Int. Cl. H01L 29/739; H01L 29/78

(52) U.S. Cl. 257/141; 257/336; 257/E29.197; 257/E29.256

(57) ABSTRACT

A semiconductor device in which: reed-shaped portions of an emitter layer of a second conductivity type are discretely formed on a surface of a base layer in a first vertical direction that is a direction vertical to a direction from an emitter electrode to a collector electrode; in a region adjoining the emitter layer, an interface of the contact layer on a side of the collector electrode is formed up to directly beneath an interface of the gate electrode on a side of the emitter electrode; and directly beneath the emitter layer, the interface of the contact layer on the side of the collector electrode is formed closer to the emitter electrode than to the interface of the gate electrode on the side of the emitter electrode.

### BACKGROUND OF THE INVENTION

(1) Field of the Invention

The present invention relates to a semiconductor device, particularly to a semiconductor device such as a lateral insulated gate bipolar transistor having a high withstand voltage.

(2) Description of the Related Art

A power device which has a high withstand voltage and applies a large amount of current is used for a switching power supply. As this power device, an insulated gate field effect transistor (hereinafter, MOSFET) which performs switching operation according to the voltage applied to an insulated gate and an insulated gate bipolar transistor (hereinafter, IGBT) are used.

The switching operation of the IGBT is described below. Generally, to turn ON the IGBT, a positive gate voltage is applied to between an emitter electrode and a gate electrode, so that a p-type base layer is inverted, and thereby a channel is formed. At this time, when a positive collector voltage is applied between the emitter electrode and the collector electrode, an electron current flows from an n-type emitter layer to an n⁻-type extended drain layer via a p-type base layer. At this time, a pnp bipolar transistor made up of a p-type collector layer, an n⁻-type drain layer, and a p-type base layer is activated, so that holes are injected from the p-type collector layer into the p-type base layer via the n⁻-type extended drain layer. These holes are supplied by a collector electrode electrically connected to the p-type collector layer. The holes injected into the p-type base layer then flow toward the emitter electrode electrically connected to the p-type base layer and the n-type emitter layer. The electric current which flows from the collector electrode to the emitter electrode as a result of the operation described above is referred to as a collector current. On the other hand, to turn OFF the IGBT, the electron current which flows from the n-type emitter layer to the n⁻-type extended drain layer via the p-type base layer is interrupted by nulling the gate voltage between the emitter electrode and the gate electrode. At this time, the pnp bipolar transistor does not operate, either, nor does the collector current flow.

Next, a latchup phenomenon occurring in the IGBT is described. When the IGBT is on, holes are injected from the p-type collector layer into the p-type base layer by the pnp bipolar operation of the p-type collector layer, the n⁻-type extended drain layer, and the p-type base layer. On the other hand, in the IGBT, a parasitic npn bipolar transistor is formed by the n⁻-type extended drain layer, the p-type base layer, and the n-type emitter layer. When holes are injected, by such bipolar operation, into the p-type base layer formed directly beneath the n-type emitter layer, a voltage drop is caused by the resistance of the p-type base layer and a hole current. When the potential difference between the p-type base layer and the n-type emitter layer is equal to or greater than a junction voltage, the parasitic bipolar transistor turns on, and the electron current flows from the n-type emitter layer to the n⁻-type extended drain layer via the p-type base layer. The turn-on of the parasitic bipolar transistor disables the switching operation through control of gate voltage, and in the worst case, may destroy the power device. As described above, the phenomenon in which the hole current flowing into the p-type base layer turns on the parasitic npn bipolar transistor is referred to as latchup. In addition, the collector current at the time of occurrence of latchup is referred to as a latchup current.

The latchup caused by the hole current occurs not only in the pnp bipolar operation but also in an avalanche state. When using a power device such as the IGBT as the switching power supply, an inductance load is normally used. When the IGBT is turned off, the collector voltage of the IGBT increases to several hundred volts. At this time, when the collector voltage increases to be equal to or greater than a breakdown voltage, the avalanche state occurs in which a large amount of electrons and holes are generated between the n⁻-type extended drain layer and the p-type base layer. The holes generated in the avalanche state flow into the p-type base region. At this time, a latchup occurs as in the mechanism described above, leading to the destruction of the power device. The latchup caused by the avalanche state as described above occurs not only in the IGBT but also in the MOSFET. This is because the MOSFET also includes an npn parasitic bipolar transistor made up of the n⁻-type extended drain layer, the p-type base layer, and the n-type source layer. In the avalanche state, the potential difference between the p-type base layer and the n-type source layer becomes equal to or greater than a junction voltage, so that a latchup is caused as in the case of the IGBT. As described above, it is necessary to improve the avalanche-withstanding capability of the IGBT and the MOSFET, considering the possibility of a latchup occurring therein.

Thus, as a conventional semiconductor device, a lateral insulated gate bipolar transistor (hereinafter, L-IGBT) which aims to increase latchup current is described. FIG. 16A is a plan view for describing a structure of a semiconductor device according to a conventional example. In addition, FIGS. 16B and 16C are cross-sectional views for describing the structure of the semiconductor device according to the conventional example, and specifically are cross-sectional views taken along on line B-B′ and C-C′ in FIG. 16A.

In the L-IGBT shown in this conventional example, an n-type extended drain layer 102 is formed on the surface of a p-type semiconductor substrate 101, and an n-type buffer layer 103 is formed on the surface of the n-type extended drain layer 102, and on the surface thereon, a p-type collector layer 104 is formed almost enclosed by the n-type buffer layer. The collector electrode 105 is electrically connected to the p-type collector layer 104. In addition, an interlayer film 107 is formed on the surface of the n″-type extended drain layer 102 via a field insulating film 106.

On the other hand, on the surface of the semiconductor substrate 101, a p-type base layer 108 is formed at a distance from the p-type collector layer 104. On the surface of the p-type base layer 108, an n-type emitter layer 109 in which reed-shaped portions are discretely formed. Here, the reed-shaped portions of the n-type emitter layer 109 are discretely formed in a direction vertical to a direction from the n-type emitter layer 109 to the p-type collector layer 104. In addition, on the surface of the p-type base layer 108, a p⁺-type contact layer 110 is formed down to a region deeper than the n-type emitter layer 109. An emitter electrode 111 is electrically connected to the n-type emitter layer 109 and the p⁺-type contact layer 110.

In addition, a gate electrode 113 is connected to the surface of the p-type base layer 108 via a gate oxide film 112.

Here, in the semiconductor device shown in the conventional example, the p⁺-type contact layer 110 having a lower resistance than the p-type base 108 is formed directly beneath the n-type emitter layer 109 so as to inhibit generation of a potential difference between the n-type emitter layer 109 and the p⁺-type contact layer 110, and to thereby increase the latchup current.

[Patent Reference 1] Japanese Unexamined Patent Application Publication No. 2008-16731

### SUMMARY OF THE INVENTION

However, the semiconductor device disclosed in Patent Reference 1 has a problem as below. In the L-IGBT shown in Patent Reference 1, both interfaces of the n-type emitter layer 109 and the p⁺-type contact layer 110 on the collector side are formed up to directly beneath an interface of the gate electrode on the emitter electrode side. At this time, insufficient formation of a channel in the p-type base layer 108 directly beneath the gate electrode causes a decrease in the electron current flowing from the n-type emitter layer 109 to the p-type base layer 108 directly beneath the gate electrode via the p-type base layer 108, so that ON-resistance is increased.

In view of the problem described above, the object of the present invention is to provide a semiconductor device which curbs increase in ON-resistance.

To solve the problem described above, a first semiconductor device according to a first aspect of the present invention includes: a semiconductor substrate of a first conductivity type; an extended drain layer of a second conductivity type, which is formed on a surface of the semiconductor substrate; a collector layer of the first conductivity type, which is formed on a surface of the extended drain layer; a collector electrode electrically connected to the collector layer; a base layer of the first conductivity type, which is formed at a distance from the collector layer; an emitter layer of the second conductivity type, which is made up of reed-shaped portions discretely formed on a surface of the base layer; a contact layer of the first conductivity type, which is formed from the surface of the base layer down to a region deeper than the emitter layer; an emitter electrode which electrically connects the emitter layer and the contact layer; and a gate electrode connected to the surface of the base layer via a gate oxide film, and the reed-shaped portions of the emitter layer are discretely formed in a first vertical direction that is a direction vertical to a direction from the emitter electrode to the collector electrode, a first part of an interface of the contact layer is formed up to directly beneath an interface of the gate electrode on a side of the emitter electrode, the first part being on a side of the collector electrode and in a region adjoining the emitter layer, and a second part of the interface of the contact layer is formed closer to the emitter electrode than to the interface of the gate electrode on the side of the emitter electrode, the second part being on the side of the collector electrode and directly beneath the emitter layer.

According to the first semiconductor device according to the first aspect of the present invention, the contact layer having a lower resistance than the base layer is formed directly beneath the emitter layer, thereby inhibiting occurrence of a potential difference between the emitter layer and the contact layer and increasing the latchup current. In addition, in the first semiconductor device according to the present invention, it is possible to increase an avalanche resistance.

Furthermore, in the first semiconductor device according to the first aspect of the present invention, a first part of an interface of the contact layer is formed up to directly beneath an interface of the gate electrode on a side of the emitter electrode, the first part being on a side of the collector electrode and in a region adjoining the emitter layer, and a second part of the interface of the contact layer is formed closer to the emitter electrode than to the interface of the gate electrode on the side of the emitter electrode, the second part being on the side of the collector electrode and directly beneath the emitter layer. Thereby, since a channel is sufficiently formed in a base layer directly beneath the gate electrode, the current flowing from the emitter layer via the base layer directly beneath the gate electrode is not caused to decrease. In other words, it is possible to curb increase in ON-resistance.

In addition, in the first semiconductor device according to the first aspect of the present invention, it is preferable that 0.5 μm<LN<1.5 μm be satisfied where LN is a distance from the second part to directly beneath a gate.

Thus, it is possible to curb decrease in the latchup current while continuously curbing increase in ON-resistance.

In addition, in the first semiconductor device according to the first aspect of the present invention, it is preferable that 7Ω<RP<200Ω be satisfied where RP is a resistance in the first vertical direction defined by the base layer and the contact layer that are present directly beneath the emitter layer.

Thus, it is possible to increase the latchup current while continuously curbing increase in ON-resistance. Specifically, it is possible to satisfy: latchup current>100 A/cm².

In addition, in the first semiconductor device according to the first aspect of the present invention, it is preferable that 0.3 μm<WN<2.0 μm be satisfied where WN is a length in the first vertical direction of the emitter layer.

Thus, it is possible to satisfy 7Ω<RP<200Ω while continuously curbing increase in ON-resistance.

In addition, in the first semiconductor device according to the first aspect of the present invention, it is preferable that the first semiconductor device include a top semiconductor layer of the first conductivity type in a surface portion of the extended drain layer.

Thus, since the top semiconductor layer is further formed inside the extended drain layer, it is also possible, at turn-off time in the IGBT operation, to efficiently extract excessive carriers remaining on the semiconductor substrate through the top semiconductor layer.

Furthermore, with this structure, a depletion layer is likely to expand within the extended drain layer at the time of reverse bias, thus allowing highly-concentrated impurities to be contained in the extended drain layer while maintaining a high withstand voltage at the same time, so that it becomes possible to shorten the lifetime of a small number of carriers within the extended drain layer and thus improve the switching speed.

In addition, in the first semiconductor device according to a first aspect of the present invention, it is preferable that the extended drain layer further include a buried semiconductor layer of the first conductivity type.

Thus, since the buried semiconductor layer is further formed inside the extended drain layer, it is also possible, at turn-off time in the IGBT operation, to efficiently extract excessive carriers remaining on the semiconductor substrate through the buried semiconductor layer.

Furthermore, with this structure, a depletion layer is likely to expand within the extended drain layer at the time of reverse bias, thus allowing highly-concentrated impurities to be contained in the extended drain layer while maintaining a high withstand voltage at the same time, so that it becomes possible to shorten the lifetime of a small number of carriers within the extended drain layer and thus improve the switching speed.

To solve the problem described above, a second semiconductor device according to a second aspect of the present invention includes: a semiconductor substrate of a first conductivity type; an extended drain layer of a second conductivity type, which is formed on a surface of the semiconductor substrate; a collector layer of the first conductivity type, which is formed on a surface of the extended drain layer; a drain layer of the second conductivity type, which is formed on the surface of the extended drain layer; a collector-drain electrode electrically connected to the collector layer and the drain layer; a base layer of the first conductivity type, which is formed at a distance from the collector layer and the drain layer; an emitter-source layer of the second conductivity type, which is made up of reed-shaped portions discretely formed on a surface of the base layer; a contact layer of the first conductivity type, which is formed from the surface of the base layer down to a region deeper than the emitter-source layer; an emitter-source electrode which electrically connects the emitter-source layer and the contact layer; and a gate electrode connected to the surface of the base layer via a gate oxide film, and the reed-shaped portions of the emitter-source layer are discretely formed in a second vertical direction that is a direction vertical to a direction from the emitter-source electrode to the collector-drain electrode, a first part of an interface of the contact layer is formed up to directly beneath an interface of the gate electrode on a side of the emitter-source electrode, the first part being on a side of the collector-drain electrode and in a region adjoining the emitter-source layer, and a second part of the interface of the contact layer is formed closer to the emitter-source electrode than to the interface of the gate electrode on the side of the emitter-source electrode, the second part being on the side of the collector-drain electrode and directly beneath the emitter-source layer.

According to the second semiconductor device in a second aspect of the present invention, the contact layer having a lower resistance than the base layer is formed directly beneath the emitter-source layer, thus inhibiting occurrence of a potential difference between the emitter-source layer and the contact layer and thereby increasing the latchup current. In addition, in the second semiconductor device according to the present invention, it is possible to increase the avalanche resistance.

Furthermore, in the second semiconductor device according to the second aspect of the present invention, a first part of an interface of the contact layer is formed up to directly beneath an interface of the gate electrode on a side of the emitter-source electrode, the first part being on a side of the collector-drain electrode and in a region adjoining the emitter-source layer, and a second part of the interface of the contact layer is formed closer to the emitter-source electrode than to the interface of the gate electrode on the side of the emitter-source electrode, the second part being on the side of the collector-drain electrode and directly beneath the emitter-source layer. Thereby, since a channel is sufficiently formed in the base layer directly beneath the gate electrode, the current flowing from the emitter-source layer via the base layer directly beneath the gate electrode is not caused to decrease. In other words, it is possible to curb the increase in ON-resistance.

In addition, in the second semiconductor device according to the second aspect of the present invention, it is preferable that 0.5 μm<LN′<1.5 μm be satisfied where LN′ is a distance from the second part to directly beneath a gate.

Thus, it is also possible to curb decrease in the latch up current while continuously curbing increase in ON-resistance.

In addition, in the second semiconductor device according to the second aspect of the present invention, it is preferable that 7Ω<RP′<200Ω be satisfied where RP′ is a resistance in the second vertical direction defined by the base layer and the contact layer that are present directly beneath the emitter-source layer.

Thus, it is possible to curb decrease in the latchup current while continuously curbing increase in ON-resistance. Specifically, it is possible to satisfy: latchup current>100 A/cm².

In addition, in the second semiconductor device according to the second aspect of the present invention, it is preferable that 0.3 μm<WN′<2.0 μm be satisfied where WN′ is a length in the second vertical direction of the emitter-source layer.

Thus, it is possible to satisfy 7Ω<RP′<200Ω while continuously curbing increase in ON-resistance.

In addition, in the second semiconductor device according to the second aspect of the present invention, it is preferable that the second semiconductor device include a top semiconductor layer of the first conductivity type in a surface portion of the extended drain layer.

Thus, since the top semiconductor layer is further formed inside the extended drain layer, it is also possible, at turn-off time in the IGBT operation, to efficiently extract excessive carriers remaining on the semiconductor substrate through the top semiconductor layer.

Furthermore, with this structure, a depletion layer is likely to expand within the extended drain layer at the time of reverse bias, thus allowing highly-concentrated impurities to be contained in the extended drain layer while maintaining a high withstand voltage at the same time, so that it becomes possible to shorten the lifetime of a small number of carriers within the extended drain layer and thus improve the switching speed.

In addition, in the second semiconductor device according to the second aspect of the present invention, it is preferable that the extended drain layer further include a buried semiconductor layer of the first conductivity type electrically connected to the base layer.

Thus, since the buried semiconductor layer is further formed inside the extended drain layer, it is also possible, at turn-off time in the IGBT operation, to efficiently extract excessive carriers remaining on the semiconductor substrate through the buried semiconductor layer.

Furthermore, with this structure, a depletion layer is likely to expand within the extended drain layer at the time of reverse bias, thus allowing highly-concentrated impurities to be contained in the extended drain layer while maintaining a high withstand voltage at the same time, so that it becomes possible to shorten the lifetime of a small number of carriers within the extended drain layer and thus improve the switching speed.

To solve the problem described above, a third semiconductor device according to a third aspect of the present invention includes: a semiconductor substrate of a first conductivity type; an extended drain layer of a second conductivity type, which is formed on a surface of the semiconductor substrate; a drain layer of the second conductivity type, which is formed on a surface of the extended drain layer; a drain electrode electrically connected to the drain layer; a base layer of the first conductivity type, which is formed at a distance from the drain layer; a source layer of the second conductivity type, which is made up of reed-shaped portions discretely formed on a surface of the base layer; a contact layer of the first conductivity type, which is formed from the surface of the base layer down to a region deeper than the source layer; a source electrode which electrically connects the source layer and the contact layer; and a gate electrode connected to the surface of the base layer via a gate oxide film, and the reed-shaped portions of the source layer are discretely formed in a third vertical direction that is a direction vertical to a direction from the source electrode to the drain electrode, a first part of an interface of the contact layer is formed up to directly beneath an interface of the gate electrode on a side of the source electrode, the first part being on a side of the drain electrode and in a region adjoining the source layer, and a second part of the interface of the contact layer is formed closer to the source electrode than to the interface of the gate electrode on the side of the source electrode, the second part being on the side of the drain electrode and directly beneath the source layer.

According to the third semiconductor device according to the third aspect of the present invention, since the contact layer having a lower resistance than the base layer is formed directly beneath the source layer, the occurrence of a potential difference between the source layer and the contact layer is inhibited, so that the latchup current can be increased. That is, in the third semiconductor device according to the present invention, it is possible to increase the avalanche resistance.

Furthermore, in the third semiconductor device according to the third aspect of the present invention, a first part of an interface of the contact layer is formed up to directly beneath an interface of the gate electrode on a side of the source electrode, the first part being on a side of the drain electrode and in a region adjoining the source layer, and a second part of the interface of the contact layer is formed closer to the source electrode than to the interface of the gate electrode on the side of the source electrode, the second part being on the side of the drain electrode and directly beneath the source layer. Thereby, since sufficient channel is formed in the base layer directly beneath the gate electrode, the current flowing from the source layer to the base layer directly beneath the gate electrode is not caused to decrease. In other words, it is possible to curb the increase in ON-resistance.

In addition, in the third semiconductor device according to the third aspect of the present invention, it is preferable that 0.5 μm<LN″<1.5 μm be satisfied where LN″ is a distance from the second part to directly beneath a gate.

Thus, it is possible to curb the decrease in the avalanche resistance while continuously curbing increase in ON-resistance.

In addition, in the third semiconductor device according to the third aspect of the present invention, it is preferable that 7Ω<RP″<200Ω be satisfied where RP″ is a resistance in the third vertical direction defined by the base layer and the contact layer that are present directly beneath the source layer.

Thus, it is possible to curb decrease in the latchup current while continuously curbing increase in ON-resistance. Specifically, in time of avalanche destruction, it is possible to satisfy: current flowing through the source>100 A/cm².

In addition, in the third semiconductor device according to the third aspect of the present invention, it is preferable that 0.3 μm<WN″<2.0 μm be satisfied where WN″ is a length in the third vertical direction of the source layer.

Thus, it is possible to satisfy 7Ω<RP″<200Ω while curbing increase in ON-resistance.

In addition, in the third semiconductor device according to the third aspect of the present invention, it is preferable that the semiconductor device include a top semiconductor layer of the first conductivity type connected to the base layer, in a surface portion of the extended drain layer.

With this structure, a depletion layer is likely to expand within the extended drain layer at the time of reverse bias, thus allowing highly-concentrated impurities to be contained in the extended drain layer while maintaining a high withstand voltage at the same time, thereby achieving low resistance of the extended drain layer. That is, it is possible to decrease ON-resistance.

In addition, in the third semiconductor device according to the third aspect of the present invention, it is preferable that the extended drain layer include a buried semiconductor layer of the first conductivity type electrically connected to the base layer.

With this structure, a depletion layer is likely to expand within the extended drain layer at the time of reverse bias, thus allowing highly-concentrated impurities to be contained in the extended drain layer while maintaining a high withstand voltage at the same time, thereby achieving low resistance of the extended drain layer. That is, it is possible to decrease ON-resistance.

As described above, according to the present invention, a first part of an interface of the contact layer is formed up to directly beneath an interface of the gate electrode on a side of the emitter electrode, the first part being on a side of the collector electrode and in a region adjoining the emitter layer, and a second part of the interface of the contact layer is formed closer to the emitter electrode than to the interface of the gate electrode on the side of the emitter electrode, the second part being on the side of the collector electrode and directly beneath the emitter layer. With this, it is possible to curb increase in ionic resistance without introducing a new process.

Furthermore, regarding the base layer and the contact layer that are present directly beneath the emitter layer, it is possible to satisfy: latchup current>100 A/cm² without introducing a new process, by satisfying 7Ω<RP<200Ω where RP represents a resistance vertical to a direction from the emitter electrode to the collector electrode.

### FURTHER INFORMATION ABOUT TECHNICAL BACKGROUND TO THIS APPLICATION

The disclosure of Japanese Patent Application No. 2009-38162 filed on Feb. 20, 2009 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a plan view showing a structure of a semiconductor device according to a first embodiment of the present invention;

FIG. 1B is a B-B′ cross-sectional view of the semiconductor device shown in FIG. 1A;

FIG. 1C is a C-C′ cross-sectional view of the semiconductor device shown in FIG. 1A;

FIG. 2 is a diagram of a graph showing a relationship between a collector current and a latchup current in the case of varying a distance LN;

FIG. 3D is a plan view enlarging a region surrounded by a dotted line D in the semiconductor device shown in FIG. 1A;

FIG. 3E is a cross-sectional view taken along with line E-E′ in the semiconductor device shown in FIG. 3D;

FIG. 3F is a cross-sectional view taken along with line F-F′ in the semiconductor device shown in FIG. 3D;

FIG. 4 is a diagram showing a relationship between a collector current and a latchup current in the case of varying a combined resistance RP;

FIG. 5A is a plan view showing a structure of the semiconductor device according to a first variation of the first embodiment;

FIG. 5B is a cross-sectional view taken along with line B-B′ in the semiconductor device shown in FIG. 5A;

FIG. 5C is a cross-sectional view taken along with line C-C′ in the semiconductor device shown in FIG. 5A;

FIG. 6A is a plan view showing a structure of the semiconductor device according to a second variation in the first embodiment;

FIG. 6B is a cross-sectional view taken along with line B-B′ in the semiconductor device shown in FIG. 6A;

FIG. 6C is a cross-sectional view taken along with line C-C′ in the semiconductor device shown in FIG. 6A;

FIG. 7 is a plan view showing a structure of the semiconductor device according to a second embodiment of the present invention;

FIG. 8A is a plan view enlarging a region A shown in FIG. 7;

FIG. 8B is a cross-sectional view taken along with line B-B′ in the semiconductor device shown in FIG. 8A;

FIG. 8C is a cross-sectional view taken along with line C-C′ in the semiconductor device shown in FIG. 8A;

FIG. 9D is a plan view enlarging a region surrounded by a dotted line D in the semiconductor device shown in FIG. 8A;

FIG. 9E is a cross-sectional view taken along with line E-E′ in the semiconductor device shown in FIG. 9D;

FIG. 9F is a cross-sectional view taken along with line F-F′ in the semiconductor device shown in FIG. 9D;

FIG. 10A is a plan view showing a structure of the semiconductor device according to a first variation of the second embodiment;

FIG. 10B is a cross-sectional view taken along with line B-B′ in the semiconductor device shown in FIG. 10A;

FIG. 10C is a cross-sectional view taken along with line C-C′ in the semiconductor device shown in FIG. 10A;

FIG. 11A is a plan view showing a structure of the semiconductor device according to a second variation of the second embodiment;

FIG. 11B is a cross-sectional view taken along with line B-B′ in the semiconductor device shown in FIG. 11A;

FIG. 11C is a cross-sectional view taken along with line C-C′ in the semiconductor device shown in FIG. 11A;

FIG. 12A is a plan view showing a structure of the semiconductor device according to a third embodiment of the present invention;

FIG. 12B is a cross-sectional view taken along with line B-B′ in the semiconductor device shown in FIG. 12A;

FIG. 12C is a cross-sectional view taken along with line C-C′ in the semiconductor device shown in FIG. 12A;

FIG. 13D is a plan view enlarging a region surrounded by a dotted line D in the semiconductor device shown in FIG. 12A;

FIG. 13E is a cross-sectional view taken along with line E-E′ in the semiconductor device shown in FIG. 13D;

FIG. 13F is a cross-sectional view taken along with line F-F′ in the semiconductor device shown in FIG. 13D;

FIG. 14A is a plan view showing a structure of the semiconductor device according to a first variation of the third embodiment of the present invention;

FIG. 14B is a cross-sectional view taken along with line B-B′ in the semiconductor device shown in FIG. 14A;

FIG. 14C is a cross-sectional view taken along with line C-C′ in the semiconductor device shown in FIG. 14A;

FIG. 15A is a plan view showing a structure of the semiconductor device according to a second variation of the third embodiment of the present invention;

FIG. 15B is a cross-sectional view taken along with line B-B′ in the semiconductor device shown in FIG. 15A;

FIG. 15C is a cross-sectional view taken along with line C-C′ in the semiconductor device shown in FIG. 15A;

FIG. 16A is a plan view for describing a structure of a semiconductor device according to a conventional example;

FIG. 16B is a cross-sectional view taken along with line B-B′ in the semiconductor device shown in FIG. 16A; and

FIG. 16C is a cross-sectional view taken along with line C-C′ in the semiconductor device shown in FIG. 16A.

### DESCRIPTION OF THE PREFERRED EMBODIMENTS

Hereinafter, a semiconductor device according to the present invention is specifically described with reference to the drawings.

### First Embodiment

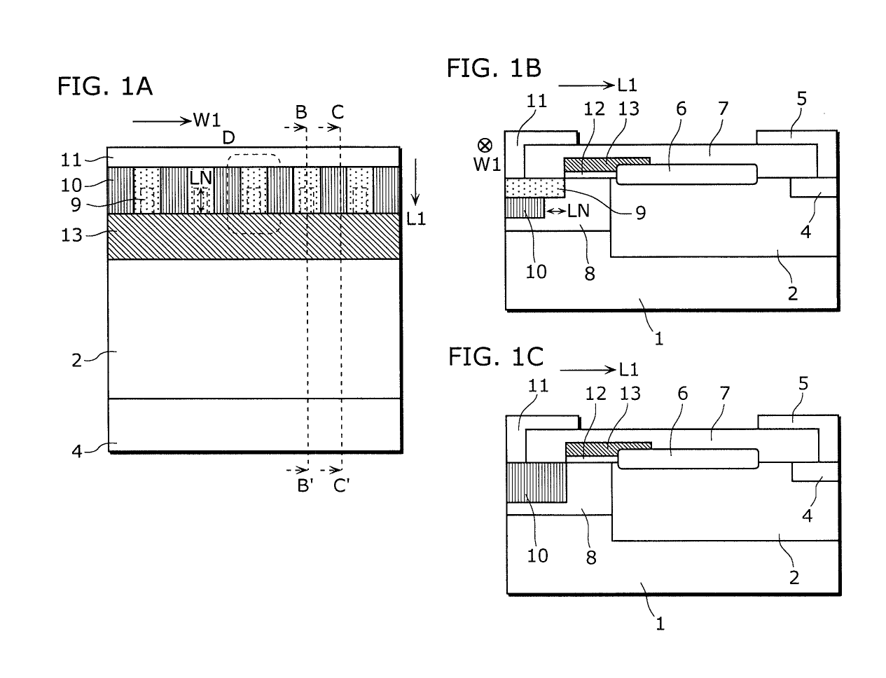

The semiconductor device according to a first embodiment of the present invention is described with reference to FIG. 1. FIG. 1A is a plan view showing a structure of the semiconductor device according to the first embodiment of the present invention. FIGS. 1B and 1C are cross-sectional views showing a structure of the semiconductor device according to the first embodiment of the present invention, showing, respectively, a cross-sectional view taken along with line B-B′ and a cross-sectional view taken along with line C-C′ of the semiconductor device shown in FIG. 1A. Note that in FIG. 1A, part of the constituent elements are not illustrated.

As shown in FIGS. 1B and 1C, the semiconductor device according to the first embodiment of the present invention includes: a semiconductor substrate 1 of a first conductivity type; an extended drain layer 2 of a second conductivity type, which is formed on a surface of the semiconductor substrate 1; a collector layer 4 of the first conductivity type, which is formed on a surface of the extended drain layer 2; a collector electrode 5 electrically connected to the collector layer 4; a base layer 8 of the first-conductivity type, which is formed at a distance from the collector layer 4; an emitter layer 9 of the second conductivity type, which is made up of reed-shaped portions discretely formed on a surface of the base layer 8; a contact layer 10 of the first conductivity type, which is formed from the surface of the based layer 8 down to a region deeper than the emitter layer 9; an emitter electrode 11 which electrically connects the emitter layer 9 and the contact layer 10; and a gate electrode 13 connected to the surface of the base layer 8 via a gate oxide film 12.

The reed-shaped portions of the emitter layer 9 are discretely formed in a first vertical direction that is vertical to a direction from the emitter electrode 11 to the collector electrode 5. In a region adjoining the emitter layer 9, an interface of the contact layer 10 on a collector electrode 5 side is formed up to a virtual line extended vertically from an interface of the emitter layer 9 on a gate electrode 13 side. The creepage surface of the contact layer 10 on the collector electrode 5 side is formed closer to the emitter electrode 11 side than to the creepage surface of the gate electrode 13 on the side of the emitter layer 9, in a region directly beneath the emitter layer 9. Hereinafter, to facilitate understanding, the description is given on the assumption that the first conductivity type is a p type and the second conductivity type is an n type. Note that the first conductivity type and the second conductivity type are not limited to this but are sufficient as long as they are opposite to each other. Here, the first vertical direction is represented by an arrow W1 in the figure, and is vertical to a direction from the emitter electrode 11 to the collector electrode 5 in the plan view, that is, as seen from an upper face side or a lower face side.

An n⁻-type extended drain layer 2 (having a concentration of approximately 1×10¹⁶/cm³ and a depth of approximately 7 μm, for example) is formed on the surface of a p-type semiconductor layer 1 (having a concentration of approximately 1×10¹⁴/cm³, for example). On the surface of the n⁻-type extended drain layer 2, a p-type collector layer 4 (having a concentration of approximately 1×10¹⁹/cm³, for example) is formed.

The collector electrode 5 is electrically connected to the p-type collector layer 4. On the surface of the n⁻-type extended drain layer 2, an interlayer film 7 is formed via a field insulating film 6.

On the surface of the p⁻-type semiconductor substrate 1, a p-type base layer 8 (having a concentration of approximately 1×10¹⁷/cm³ to 5×10¹⁷/cm³ and a depth of approximately 1.5 μm, for example) is formed. Inside the surface of the p-type base layer 8, reed-shaped portions of an n⁻-type emitter layer 9 (having a concentration of approximately 1×10²⁰/cm³ and a depth of approximately 0.5 μm, for example) are discretely formed.

In addition, a p⁺-type contact layer 10 (having a concentration of approximately 1×10¹⁸/cm³ and a depth of approximately 1 μm, for example) is formed from the surface of the p-type base layer 8 down to a region deeper than the n⁺-type emitter layer 9. The structures of the n⁺-type emitter layer 9 and the p⁺-type contact layer 10 are described later.

The n⁺-type emitter layer 9 and the p-type base layer 8 are electrically connected via the emitter electrode 11. In addition, to the surface of the p-type base layer 8, a gate electrode 13 is connected via a gate oxide film 12.

Here, the structures of the n⁺-type emitter layer 9 and the p⁺-type contact layer 10 are described. The reed-shaped portions of the n⁺-type emitter layer 9 are discretely formed in the first vertical direction (direction W1) that is vertical to the direction (direction L1) from the emitter electrode 11 to the collector electrode 5. An interface of the p⁺-type contact layer 10 on the collector electrode 5 side in a region adjoining the n⁺-type emitter layer 9 in the first vertical direction is formed up to directly beneath an interface of the gate electrode 13 on the emitter electrode 11 side so that the two interfaces are aligned. On the other hand, the interface of the p⁺-type contact layer 10 on the collector electrode 5 side, which is directly beneath the n⁺-type emitter layer 9, is formed at a position closer to the emitter electrode 11 side, in the direction L1 by the distance LN, than to directly beneath the interface of the gate electrode 13 on the emitter electrode 11 side.

Here, a larger amount of collector current flows through the interface of the p⁺-type contact layer 10 on the collector electrode 5 side in the case where the interface of the p⁺-type contact layer 10 on the collector electrode 5 side, which is directly beneath the n⁺-type emitter layer 9, is formed at a position closer to the emitter electrode 11 side, in the direction L1 by the distance LN, than to directly beneath the interface of the gate electrode 13 on the emitter electrode 11 side than in the case where the interface of the p⁺-type contact layer 10 on the collector electrode 5 side, which is directly beneath the p⁺-type emitter layer 9, is formed up to the interface of the gate electrode 13 on the emitter electrode 11 side. This is because a larger amount of electron current flows through the interface of the p⁺-type contact layer 10 on the collector electrode 5 side, from the n⁺-type emitter layer 9 to the n⁻-type extended drain layer 2 via the p-type base layer 8 directly beneath the gate oxide film 12, in the case where the interface of the p⁺-type contact layer 10 on the collector electrode 5 side, which is directly beneath the n⁺-type emitter layer 9, is formed at a position closer to the emitter electrode 11 side, in the direction L1 by the distance LN, than to directly beneath the interface of the gate electrode 13 on the emitter electrode 11 side than in the case where the interface of the p⁺-type contact layer 10 on the collector electrode 5 side directly beneath the N⁺-type emitter layer 9 is formed up to directly beneath the interface of the gate electrode 13 on the emitter electrode 11 side.

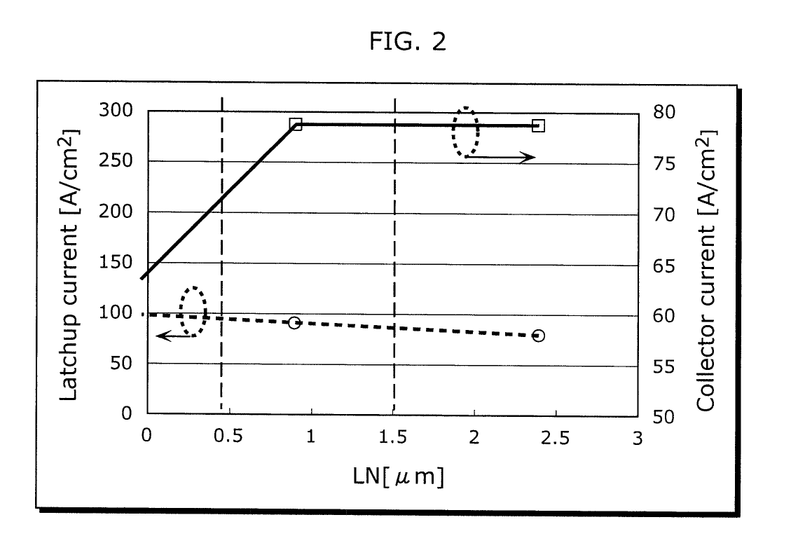

Thus, it is preferable that the distance LN be 0.5 μm<LN<1.5 μm where the interface of the p⁺-type contact layer 10 on the collector electrode 5 side and directly beneath the n⁺-type emitter layer 9 is formed at a position closer to the emitter electrode 11 side, in the direction L1 by the distance LN, than to directly beneath the interface of the gate electrode 13 on the emitter electrode 11 side. FIG. 2 shows a relationship between the collector current and the latchup current with respect to the distance LN, which is obtained using a semiconductor device having different LNs, which is experimentally manufactured by the inventors of the present invention. The collector current represents a collector current in the ON state of the IGBT, which is generated by applying 10 V between the gate and the emitter, and 6 V between the collector and the emitter. That is, it is shown that the larger the amount of collector current is, the smaller is ON-resistance. The latchup current represents the collector current when latchup is caused by the IGBT by applying 10 V between the gate and the emitter and gradually increasing the voltage between the collector and the emitter. As FIG. 2 shows, compared to the case where the collector current is 78 A/cm² in a region of LN>0.9 μm, the collector current decreases in a region of LN<0.9 μm. To keep the decrease in the collector current within a range of 10%, it is preferable that LN>0.5 μm be satisfied, that is, collector current>70 A/cm² be satisfied. In addition, when LN is increased, the latchup current gradually decreases. To satisfy: latchup current>80 A/cm², it is preferable that LN>1.5 μm be satisfied. That is, by LN satisfying 0.5 μm<LN<1.5 μm, it is possible to keep the decrease in the collector current within a range of 10% and also to curb the decrease in the latchup current.

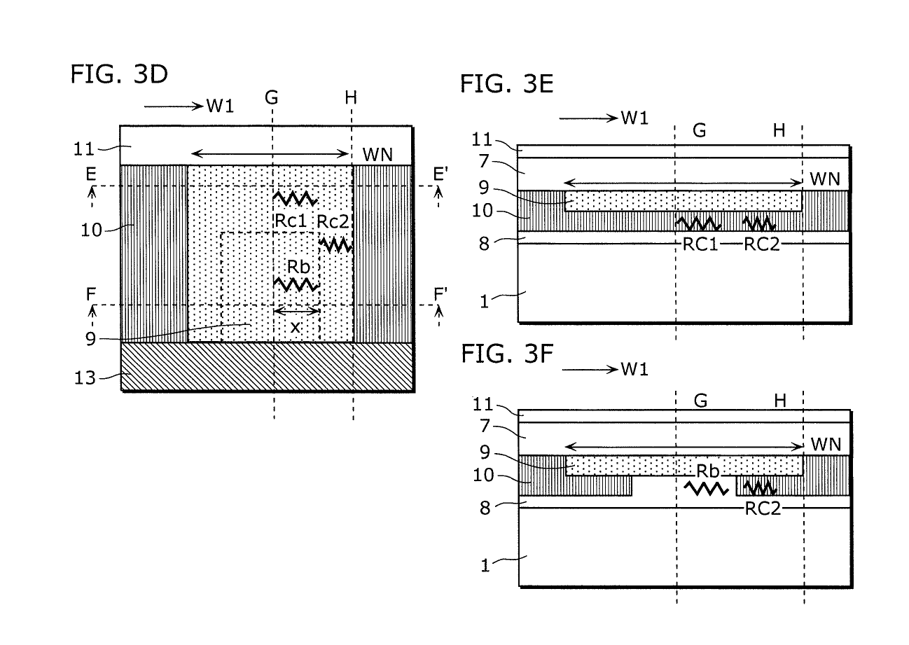

Furthermore, a resistance RP in the first vertical direction of the p-type base layer 8 and the p⁺-type contact layer 10 that are present directly beneath the n⁺-type emitter layer 9 is described. FIG. 3D is a plan view enlarging a region surrounded by a dotted line D in FIG. 1A. In addition, FIGS. 3E and 3F show cross-sectional views taken along with line E-E′ and F-F′ in FIG. 3D.

The following faces are considered: a center face G in the first vertical direction of the n⁺-type emitter layer 9 made up of reed-shaped portions and a length WN in the first vertical direction, and an edge face H in the first vertical direction of the n⁺-type emitter layer 9. At this time, when holes that are present in the center face G and directly beneath the n⁺-type emitter layer 9 move to the edge face H directly beneath the n⁺-type emitter layer 9, the holes are influenced by three resistances shown below.

1. Resistance Rb of the p-type base layer 8, which is generated when the holes move from the center face G in the first vertical direction by a length X

2. Resistance Rc1 of the p⁺-type contact layer 10, which is generated when the holes move from the center face G in the first vertical direction by the length X

3. Resistance Rc2 of the p⁺-type contact layer 10, which is generated when the holes move, to the edge face H, from a point distant from the center face G in the first vertical direction by the length X.

RP is a combined resistance of these three resistances, and is represented by the expression below.

RP=(1/Rb+1/Rc1)⁻¹+Rc2

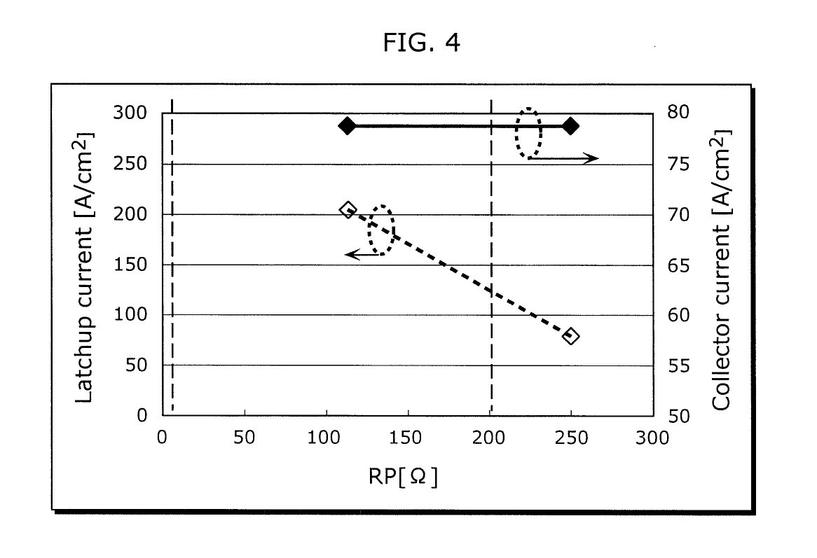

Thus, considering the combined resistance RP in the first vertical direction of the p-type base layer 8 and the P⁺-type contact layer 10 that are present directly beneath the n⁺-type emitter layer 9, it is preferable that RP be 7Ω<RP<200Ω. FIG. 4 shows a relationship between the collector current and the latchup current with respect to an amount of RP, which is obtained using a semiconductor device having different RPs, which is experimentally manufactured by the inventors of the present invention. The collector current and the latchup current are the same as those defined earlier. As FIG. 4 shows, when RP<200Ω, the latchup current can be 100 A/cm² or more. The figure also shows that the latchup current further increases when RP is smaller. In addition, the amount of the collector current is approximately 78 A/cm², and no increase in ON-resistance is observed. Considering the process of injection into the n⁺-type emitter layer 9 and the p⁺-type contact layer 10, a lower limit to RP is approximately 7Ω. Thus, by setting to 7Ω<RP<200Ω, the combined resistance RP of the p-type base layer 8 and p⁺-type contact layer 10 that are present directly beneath the n⁺-type emitter layer 9, the latchup current can be 100 A/cm² or more without causing an increase in ON-resistance.

Thus, when setting to 7Ω<RP<200Ω, the combined resistance RP of the p-type base layer 8 and the p⁺-type contact layer 10 that are present directly beneath the n⁺-type emitter layer 9, it is preferable that the length WN in the first vertical direction of the n⁺-type emitter layer 9 be 0.3 μm<WN<2.0 μm. Thus, the combined resistance RP can be 7Ω<RP<200Ω without changing the process of injection into the n-type emitter layer and the p⁺-type contact layer.

(Variation 1)

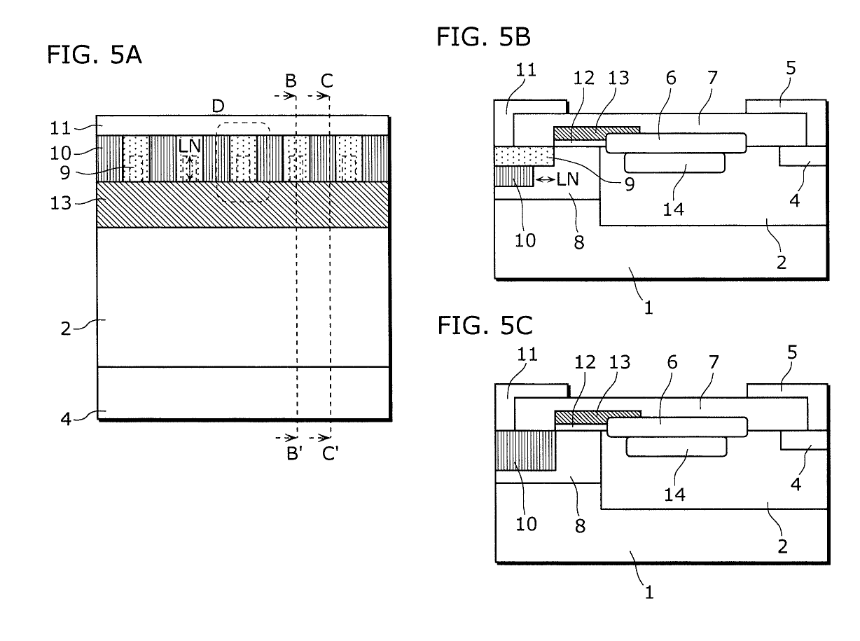

Hereinafter, a semiconductor device according to a first variation of the first embodiment is described with reference to FIG. 5. FIG. 5A is a plan view showing a structure of the semiconductor device according to the first variation of the first embodiment of the present invention. FIGS. 5B and 5C are cross-sectional views showing the structure of the semiconductor device according to the first variation of the first embodiment of the present invention, and show, respectively, cross-sectional views taken along with line B-B′ and line C-C′ in FIG. 5A. Note that in FIG. 5A, part of the constituent elements are not illustrated. The semiconductor device according to the first variation is specifically described in terms of differences from the semiconductor device according to the first embodiment.

As shown in FIGS. 5B and 5C, the semiconductor device according to the first variation has, in a surface portion of the n⁻-type extended drain layer 2, a p-type top semiconductor layer 14 which is equivalent to the p-type base layer 8 in terms of electrical potential.

With the semiconductor device according to the present variation, by providing the p-type top semiconductor layer 14 as above, it is also possible, at a turn-off time in the IGBT operation, to extract holes remaining on a p-type semiconductor substrate 1 through the p-type top semiconductor layer 14, thus reducing the time for turning off in the IGBT operation.

Furthermore, with this structure, a depletion layer is likely to expand within the n⁻-type extended drain layer 2 at the time of reverse bias, thus allowing highly-concentrated impurities to be contained in the n⁻-type extended drain layer 2 while maintaining a high withstand voltage at the same time, so that it becomes possible to shorten the lifetime of a small number of carriers within the n⁻-type extended drain layer 2 and thus improve the switching speed.

(Variation 2)

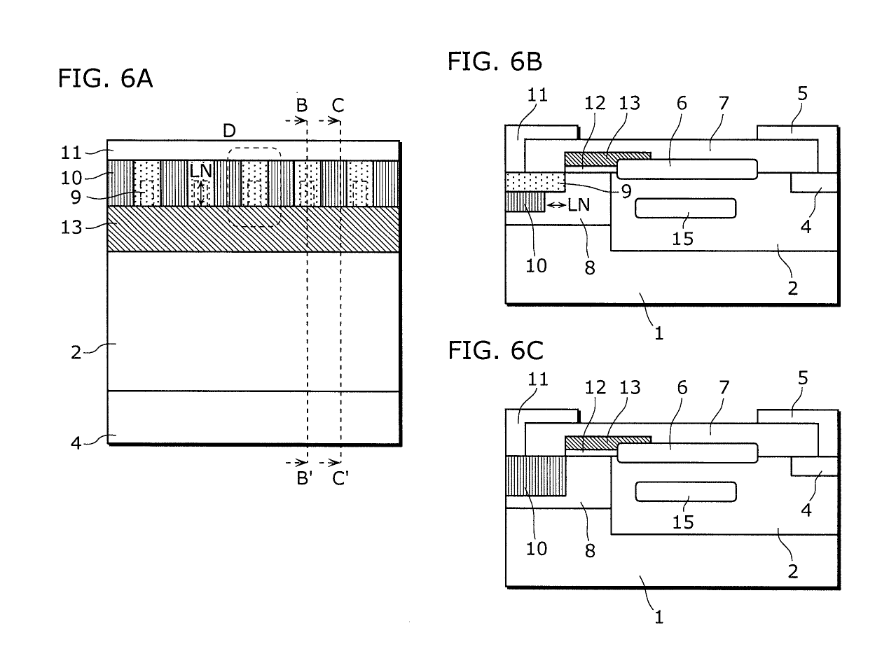

Hereinafter, a semiconductor device according to a second variation of the first embodiment is described with reference to FIG. 6. FIG. 6A is a plan view showing a structure of the semiconductor device according to the second variation of the first embodiment of the present invention. FIGS. 6B and 6C are cross-sectional views showing the structure of the semiconductor device according to the second variation of the first embodiment of the present invention, and show, respectively, cross-sectional views taken along with line B-B′ and line C-C′ in FIG. 6A. Note that in FIG. 6A, part of the constituent elements are not illustrated. The semiconductor device according to the second variation is specifically described in terms of differences from the semiconductor device according to the first embodiment.

As shown in FIGS. 6B and 6C, the semiconductor device according to the second variation includes, inside the n-type extended drain layer 2, a p-type buried semiconductor layer 15 which is equivalent to the p-type base layer 8 in terms of electrical potential.

With the semiconductor device according to the present variation, by thus providing the p-type buried semiconductor layer 15, it is also possible, at turn-off time in the IGBT operation, to extract holes remaining on the p-type semiconductor substrate 1 through the p-type buried semiconductor layer 15, thus reducing the time for turning off in the IGBT operation.

Furthermore, with this structure, a depletion layer is likely to expand within the n⁻-type extended drain layer 2 at the time of reverse bias, thus allowing highly-concentrated impurities to be contained in the n⁻-type extended drain layer 2 while maintaining a high withstand voltage at the same time, so that it becomes possible to shorten the lifetime of a small number of carriers within the n⁻-type extended drain layer 2 and thus improve the switching speed.

### Second Embodiment

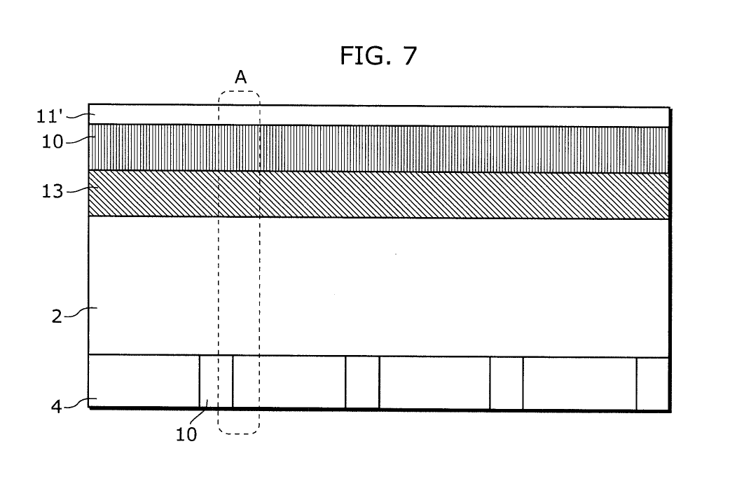

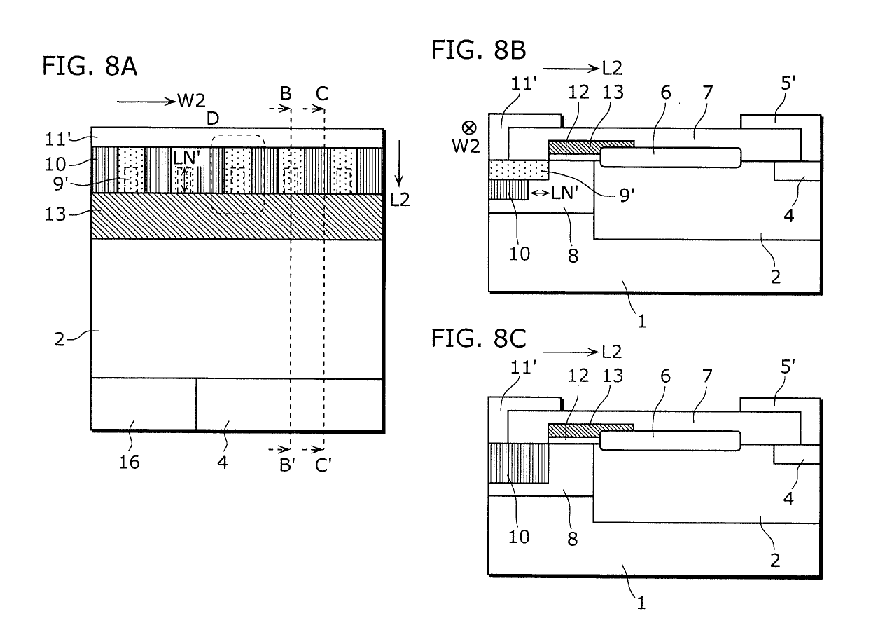

The semiconductor device according to a second embodiment of the present invention is described with reference to FIGS. 7 and 8. FIG. 7 is a plan view showing a structure of the semiconductor device according to the second embodiment of the present invention. FIG. 8A is a plan view enlarging a region A surrounded by a dotted line in FIG. 7. FIGS. 8B and 8C are cross-sectional views showing the structure of the semiconductor device according to the second embodiment of the present invention and show, respectively, cross-sectional views taken along with line B-B′ and line C-C′ in FIG. 8A. Note that in FIGS. 7 and 8A, part of the constituent elements are not illustrated.

As shown in FIGS. 8B and 8C, the semiconductor device according to the second embodiment of the present invention includes: a semiconductor substrate 1 of a first conductivity type; an extended drain layer 2 of a second conductivity type, which is formed on a surface of the semiconductor substrate 1; a collector layer 4 of the first conductivity type, which is formed on a surface of the extended drain layer 2; a drain layer 16 of the second conductivity type, which is formed on the surface of the extended drain layer 2; a collector-drain electrode 5′ electrically connected to the collector layer 4 and the drain layer 16; a base layer 8 of the first conductivity type, which is formed at a distance from the collector layer 4 and the drain layer 16; an emitter-source layer 9′ of the second conductivity type, which is made up of reed-shaped portions discretely formed on a surface of the base layer 8; a contact layer 10 of the first conductivity type, which is formed from the surface of the base layer 8 down to a region deeper than the emitter-source layer 9′; an emitter-source electrode 11′ which electrically connects the emitter-source layer 9′ and the contact layer 10; and a gate electrode 13 connected to the surface of the base layer 8 via a gate oxide film 12.

The reed-shaped portions of the emitter-source layer 9′ are discretely formed in a second vertical direction that is vertical to a direction from the emitter-source electrode 11′ to the collector-drain electrode 5′. Here, the second vertical direction is a direction represented by an arrow W2 in the figure, and is vertical to a direction from the emitter-source electrode 11′ to the collector-drain electrode 5′ in the plan view, that is, as seen from an upper face side or a lower face side.

In a region adjoining the emitter-source layer 9′, an interface of the contact layer 10 on a collector-drain electrode 5′ side is formed up to directly beneath an interface of the gate electrode 13 on an emitter-source electrode 11′ side.

An interface of the contact layer 10 on the collector-drain electrode 5′ side is formed closer to the emitter-source electrode 11′ side than to the interface of the gate electrode 13 on the emitter-source electrode 11′ side, in a region directly beneath the emitter-source layer 9′.

An n⁻-type extended drain layer 2 (having a concentration of approximately 1×10¹⁶/cm³ and a depth of approximately 7 μm, for example) is formed on the surface of the p-type semiconductor substrate 1 (having a concentration of approximately 1×10¹⁴/cm³, for example). On the surface of the n⁻-type extended drain layer 2, a p-type collector layer 4 (having a concentration of approximately 1×10¹⁹/cm³, for example) is formed. Furthermore, on the surface of the extended drain layer 2, an n⁺-type drain layer 16 (having a concentration of approximately 1×10²⁰/cm³ and a depth of approximately 0.5 μm, for example) is formed.

The collector-drain electrode 5′ is electrically connected to the p-type collector layer 4 and the n⁺-type drain layer 16. On the surface of the n⁻-type extended drain layer 2, an interlayer film 7 is formed via a field insulating film 6.

On the surface of the p⁻-type semiconductor substrate 1, a p-type base layer 8 (having a concentration of approximately 1×10¹⁷/cm³ to 5×10¹⁷/cm³ and a depth of approximately 1.5 μm, for example) is formed at a distance from the n⁻-type extended drain layer 2. Inside the surface of the p-type base layer 8, reed-shaped portions of an n⁺-type emitter-source layer 9′ (having a concentration of approximately 1×10²⁰/cm³ and a depth of approximately 0.5 μm, for example) are discretely formed.

In addition, a p⁺-type contact layer 10 (having a concentration of approximately 1×10¹⁸/cm³ and a depth of approximately 1 μm, for example) is formed from the surface of the p-type base layer 8 down to a region deeper than the n⁺-type emitter-source layer 9′. The structures of the n⁺-type emitter-source layer 9′ and the p⁺-type contact layer 10 are described later.

The n⁺-type emitter-source layer 9′ and the p-type base layer 8 are electrically connected via the emitter-source electrode 11′. In addition, a gate electrode 13 is formed on a surface of the p-type base layer 8 via a gate oxide film 12.

Here, the structures of the n⁺-type emitter-source layer 9′ and the p⁺-type contact layer 10 are described. The reed-shaped portions of the emitter-source layer 9′ are discretely formed in the second vertical direction (direction W2) that is vertical to the direction (direction L2) from the emitter-source electrode 11′ to the collector-drain electrode 5′. An interface of the p⁺-type contact layer 10 on the collector-drain electrode 5′ side in a region adjoining the n⁺-type emitter-source layer 9′ in the second vertical direction is formed up to directly beneath an interface of the gate electrode 13 on the emitter-source electrode 11′ side. On the other hand, an interface of the p⁺-type contact layer 10 on the collector-drain electrode 5′ side, which is directly beneath the n⁺-type emitter-source layer 9′, is formed closer to the emitter-source electrode 11′ side, in the direction L2 by the distance LN′, than to directly beneath the interface of the gate electrode 13 on the emitter-source electrode 11′ side.

Thus, by forming the p-type collector layer 4 and the n⁺-type drain layer 16 on the surface of the n⁻-type extended drain layer 2, it is possible to cause an MOSFET to operate when the collector current flowing in the semiconductor device is relatively small, and also to cause an IGBT to operate when the collector current increases, thereby allowing selective use of these two types of transistors the MOSFET and the IGBT by using a single device. Thus, it becomes possible to cause the MOSFET to operate in standby time and light-load time and cause the IGBT to operate in heavy-load time, thereby allowing reduction of loss across the whole range, from light load to heavy load.

Here, a larger amount of collector current flows through the interface of the p⁺-contact layer 10 on the collector-drain electrode 5′ side, which is directly beneath the n⁺-type emitter-source layer 9′, in the case where the interface of the p⁺-type contact layer 10 on the collector-drain electrode 5′ side, which is directly beneath the n⁺-type emitter-source layer 9′, is formed closer to the emitter-source electrode 11′ side, in the direction L2 by the distance LN′, than to directly beneath the interface of the gate electrode 13 on the emitter-source electrode 11′ side than in the case where the interface of the p⁺-type contact layer 10 on the collector-drain electrode 5′ side, which is directly beneath the n⁺-type emitter-source layer 9′, is formed up to directly beneath the interface of the gate electrode 13 on the emitter-source electrode 11′ side. This is because a larger amount of electron current flows through the interface of the P⁺-type contact layer 10 on the collector-drain electrode 5′ side, which is directly beneath the n⁺-type emitter-source layer 9′, from the n⁺-type emitter-source layer 9′ to the n⁻-type extended drain layer 2 via the p-type base layer 8 directly beneath the gate oxide film 12 in the case where the interface of the p⁺-type contact layer 10 on the collector-drain electrode 5′ side, which is directly beneath the n⁺-type emitter-source layer 9′, is formed at a position closer to the emitter-source electrode 11′ side, in the direction L2 by the distance LN′, than to directly beneath the interface of the gate electrode 13 on the emitter-source electrode 11′ side than in the case where the interface of the p⁺-type contact layer 10 on the collector-drain side directly beneath the n⁺-type emitter-source layer 9′ is formed up to directly beneath the interface of the gate electrode 13 on the emitter-source electrode 11′ side.

Thus, as in the case of the semiconductor device according to the first embodiment, it is preferable that the distance of LN′ be 0.5 μm<LN′<1.5 μm in the case where the interface of the p⁺-type contact layer 10 on the collector-drain electrode 5′ side, which is directly beneath the n⁺-type emitter-source layer 9′, is formed at a position closer to the emitter-source electrode 11′ side, in the direction L2 by the distance LN′, than to directly beneath the interface of the gate electrode 13 on the emitter-source electrode 11′ side. By satisfying 0.5 μm<LN′<1.5 μm, it is possible to keep the decrease in the collector current within a range of 10% and also to curb the decrease in the latchup current.

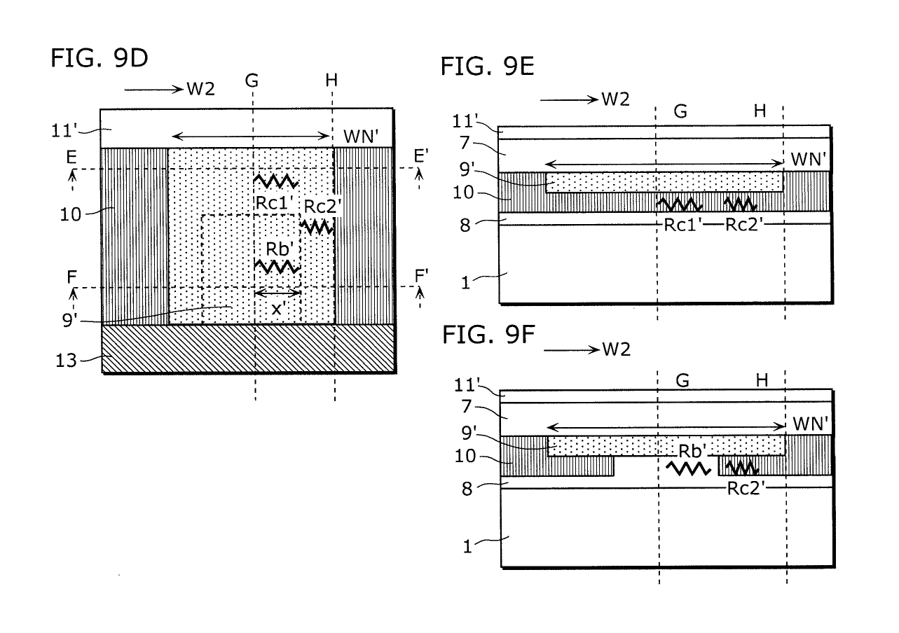

Furthermore, a resistance RP′ in the second vertical direction of the p-type base layer 8 and the p⁺-type contact layer 10 that are directly beneath the n⁺-type emitter-source layer 9′ is described. FIG. 9D is a plan view enlarging a region surrounded by a dotted line D in FIG. 8A. In addition, FIGS. 9E and 9F are cross-sectional views taken along with line E-E′ in FIG. 8D.

The following faces are considered: a center face G in the second vertical direction of the n⁺-type emitter-source layer 9′ made up of reed-shaped portions and a length WN′ in the first second direction, and an edge face H in the second vertical direction of the n⁺-type emitter-source layer 9′. At this time, when holes that are present in the center face G and directly beneath the n⁺-type emitter-source layer 9′ move to the edge face H directly beneath the n⁺-type emitter-source layer 9′, the holes are influenced by three resistances shown below.

1. Resistance Rb′ of the p-type base layer 8, which is generated when the holes move from the center face G in the second vertical direction by a length X′

2. Resistance Rc1′ of the p⁺-type contact layer 10, which is generated when the holes move from the center face G in the second vertical direction by the length X′

3. Resistance Rc2′ of the p⁺-type contact layer 10, which is generated when the holes move, to the edge face H, from a point distant from the center face G in the second vertical direction by the length X′.

RP′ is a combined resistance of these three resistances, and is represented by the expression below.

RP′=(1/Rb′+1/Rc1′)⁻1+Rc2′

Considering the combined resistance RP′ in the second vertical direction of the p-type base layer 8 and the P⁺-type contact layer 10 that are directly beneath the n⁺-type emitter-source layer 9′, it is preferable that RP′ be 7Ω<RP′<200Ω as in the case of the semiconductor device according to the first embodiment. By setting to 7Ω<RP′<200Ω, the combined resistance RP′ of the p-type base layer 8 and the p⁺-type contact layer 10 that are present directly beneath the n⁺-type emitter-source layer 9′, the latchup current can be 100 A/cm² or more without causing an increase in ON-resistance.

Thus, when setting to 7Ω<RP′<200Ω, the combined resistance RP′ of the p-type base layer 8 and the p⁺-type contact layer 10 that are present directly beneath the n⁺-type emitter-source layer 9′, it is preferable that the length WN′ in the second vertical direction of the n⁺-type emitter-source layer 9′ be 0.3 μm<WN′<2.0 μm. Thus, the combined resistance RP′ can be 7Ω<RP′<200Ω without changing the process of injection into the n-type emitter layer and the p⁺-type contact layer.

(Variation 1)

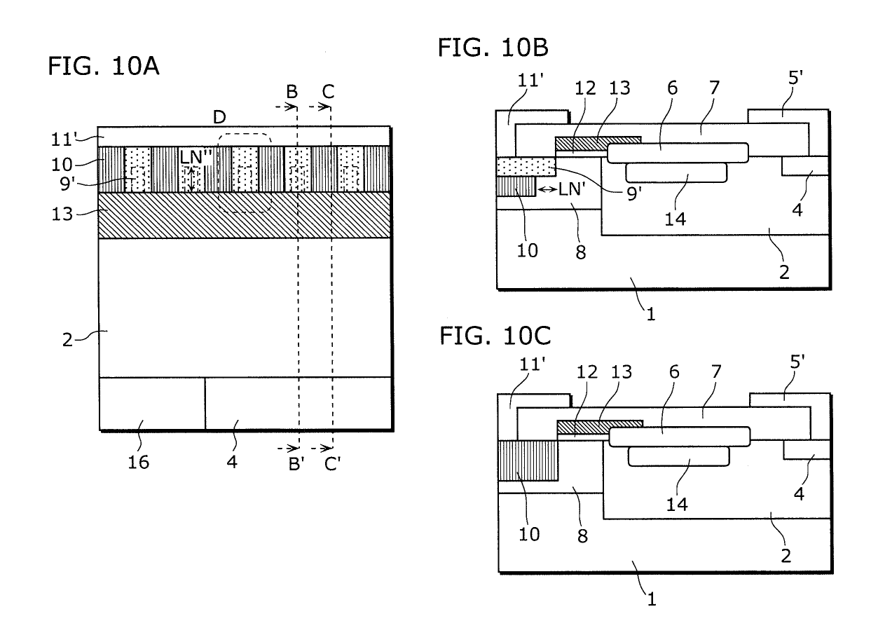

Hereinafter, a semiconductor device according to a first variation of the second embodiment is described with reference to FIG. 10. FIG. 10A is a plan view showing a structure of the semiconductor device according to the first variation of the second embodiment of the present invention. FIGS. 10B and 10C are cross-sectional views showing the structure of the semiconductor device according to the first variation of the second embodiment of the present invention, and show, respectively, cross-sectional views taken along with line B-B′ and line C-C′ in FIG. 10A. Note that in FIG. 10A, part of the constituent elements are not illustrated. The semiconductor device according to the first variation is specifically described in terms of differences from the semiconductor device according to the second embodiment.

As shown in FIGS. 10B and 10C, the semiconductor device according to the first variation has, in a surface portion of the n⁻-type extended drain layer 2, a p-type top semiconductor layer 14 which is equivalent to the p-type base layer 8 in terms of electrical potential.

With the semiconductor device according to the present variation, by providing the p-type top semiconductor layer 14 as above, it is also possible, at turn-off time in the IGBT operation, to extract holes remaining on a p-type semiconductor substrate through the p-type top semiconductor layer 14, thus reducing the time for turning off in the IGBT operation.

Furthermore, with this structure, a depletion layer is likely to expand within the n⁻-type extended drain layer 2 at the time of reverse bias, thus allowing highly-concentrated impurities contained in the n⁻-type extended drain layer 2 while maintaining a high withstand voltage at the same time, so that it becomes possible to shorten the lifetime of a small number of carriers within the n⁻-type extended drain layer 2 and thus improve the switching speed.

(Variation 2)

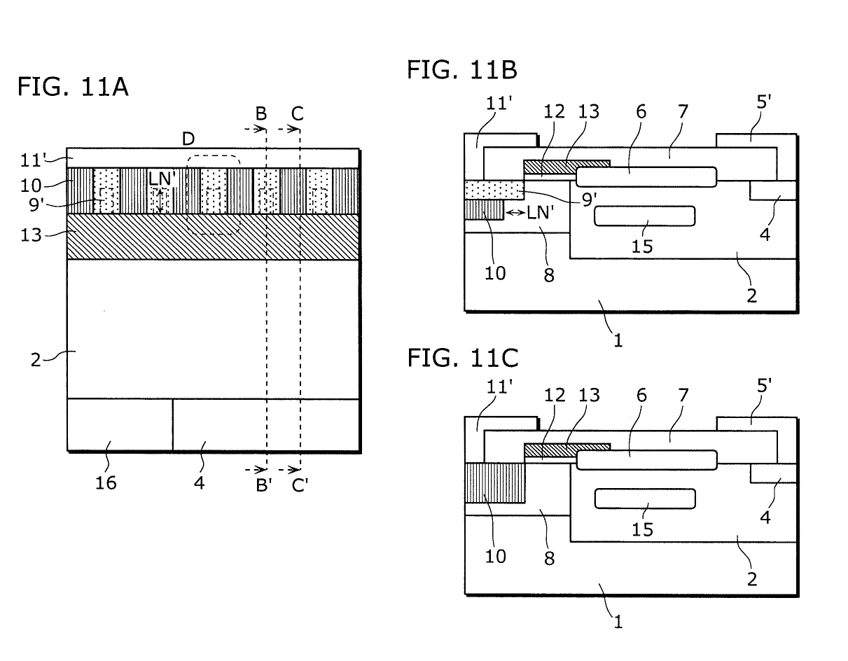

Hereinafter, a semiconductor device according to a second variation of the second embodiment is described with reference to FIG. 11. FIG. 11A is a plan view showing a structure of the semiconductor device according to the second variation of the second embodiment of the present invention. FIGS. 11B and 11C are cross-sectional views showing the structure of the semiconductor device according to the second variation of the second embodiment of the present invention, and show, respectively, cross-sectional views taken along with line B-B′ and line C-C′ in FIG. 11A. Note that in FIG. 11A, part of the constituent elements are not illustrated. The semiconductor device according to the first variation is specifically described in terms of differences from the semiconductor device according to the first embodiment.

As shown in FIGS. 11B and 11C, the semiconductor device according to the second variation includes, inside the n⁻-type extended drain layer 2, a p-type buried semiconductor layer 15 which is equivalent to the p-type base layer 8 in terms of electrical potential.

With the semiconductor device according to the present variation, by thus providing the p-type buried semiconductor layer 15, it is also possible, at turn-off time in the IGBT operation, to extract holes remaining on the p-type semiconductor substrate 1 through the p-type top semiconductor layer 15, thus reducing the time for turning off in the IGBT operation.

Furthermore, with this structure, a depletion layer is likely to expand within the n⁻-type extended drain layer 2 at the time of reverse bias, thus allowing highly-concentrated impurities contained in the n⁻-type extended drain layer 2 while maintaining a high withstand voltage at the same time, so that it becomes possible to shorten the lifetime of a small number of carriers within the n⁻-type extended drain layer 2 and thus improve switching speed.

### Third Embodiment

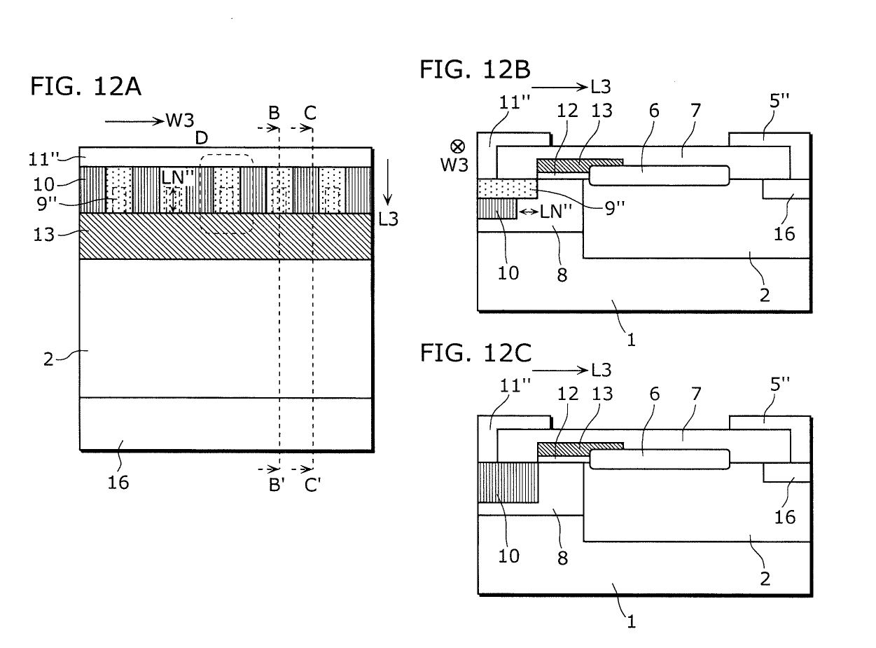

The semiconductor device according to a third embodiment of the present invention is described with reference to FIG. 12. FIG. 12A is a plan view showing a structure of the semiconductor device according to the third embodiment of the present invention. FIGS. 12B and 12C are cross-sectional views showing the structure of the semiconductor device according to the third embodiment of the present invention and show, respectively, cross-sectional views taken along with line B-B′ and line C-C′ in FIG. 12A. Note that in FIG. 12A, part of the constituent elements are not illustrated.

As shown in FIGS. 12B and 12C, the semiconductor device according to the third embodiment of the present invention includes: a semiconductor substrate 1 of a first conductivity type; an extended drain layer 2 of a second conductivity type, which is formed on a surface of the semiconductor substrate 1; a drain layer 16 of the second conductivity type, which is formed on a surface of the extended drain layer 2; a drain electrode 5″electrically connected to the drain layer; a base layer 8 of the first conductivity type, which is formed at a distance from the drain layer 16; a source layer 9″ of the second conductivity type, which is made up of reed-shaped portions discretely formed on a surface of the base layer 8; a contact layer 10 of the first conductivity type, which is formed from the surface of the base layer 8 down to a region deeper than the source layer 9″; a source electrode 11″ which electrically connects the source layer 9″ and the contact layer 10; and a gate electrode 13 connected to the surface of the base layer 8 via a gate oxide film 12.

The reed-shaped portions of the source layer 9″ are discretely formed in a third vertical direction that is vertical to a direction from the source electrode 11″ to the drain electrode 5″. Here, the third vertical direction is a direction represented by an arrow W3 in the figure, and is vertical to a direction from the source electrode 11″ to the drain electrode 5″ in the plan view, that is, as seen from an upper face side or a lower face side.

In a region adjoining the source layer 9″, an interface of the contact layer 10 on a drain electrode 5″ side is formed up to directly beneath an interface of the gate electrode 13 on a source electrode 11″ side.

An interface of the contact layer 10 on the drain electrode 5″ side is formed closer to the source electrode 11″ side than to the interface of the gate electrode 13 on the source electrode 11″ side, in a region directly beneath the source layer 9″.

An n⁻-type extended drain layer 2 (having a concentration of approximately 1×10¹⁶/cm³ and a depth of approximately 7 μm, for example) is formed on the surface of the p-type semiconductor substrate 1 (having a concentration of approximately 1×10¹⁴/cm³, for example). On the surface of the n⁻-type extended drain layer 2, an n⁺-type drain layer 16 (having a concentration of approximately 1×10²⁰/cm³ and a depth of approximately 0.5 μm, for example) is formed.

The drain electrode 5″ is electrically connected to the n-type drain layer 16. On the surface of the n⁻-type extended drain layer 2, an interlayer film 7 is formed via a field insulating film 6.

On the surface of the p⁻-type semiconductor substrate 1, a p-type base layer 8 (having a concentration of approximately 1×10¹⁷/cm³ to 5×10¹⁷/cm³ and a depth of approximately 1.5 μm, for example) is formed at a distance from the n⁻-type extended drain layer 2. Inside the surface of the p-type base layer 8, reed-shaped portions of an n⁺-type source layer 9″ (having a concentration of approximately 1×10²⁰/cm³ and a depth of approximately 0.5 μm, for example) are discretely formed.

In addition, a p⁺-type contact layer 10 (having a concentration of approximately 1×10¹⁸/cm³ and a depth of approximately 1 μm, for example) is formed from the surface of the p-type base layer 8 down to a region deeper than the n⁺-type source layer 9″. The structures of the n⁺-type source layer 9″ and the p⁺-type contact layer 10 are described later.

The n⁺-type source layer 9″ and the p-type base layer 8 are electrically connected via the source electrode 11″. In addition, a gate electrode 13 is formed on a surface of the p-type base layer 8 via a gate oxide film 12.

Here, the structures of the n⁺-type source layer 9″ and the p⁺-type contact layer 10 are described. The reed-shaped portions of the source layer 9″ are discretely formed in the third vertical direction (direction W3) that is vertical to the direction (direction L3) from the source electrode 11″ to the drain electrode 5″. An interface of the p⁺-type contact layer 10 on the drain electrode 5″ side in a region adjoining the n⁺-type source layer 9″ in the third vertical direction is formed up to directly beneath an interface of the gate electrode 13 on the source electrode 11″ side. On the other hand, an interface of the p⁺-type contact layer 10 on the drain electrode 5″ side, which is directly beneath the n⁺-type source layer 9″, is formed closer to the source electrode 11″ side, in the direction L3 by the distance LN″, than to directly beneath the interface of the gate electrode 13 on the source electrode 11″ side.

Here, a larger amount of collector current flows through the interface of the p⁺-contact layer 10 on the drain electrode 5″ side directly beneath the n⁺-type source layer 9″ in the case where the interface of the p⁺-type contact layer 10 on the drain electrode 5″ side, which is directly beneath the n⁺-type source layer 9″, is formed at a position closer to the source electrode 11″ side, in the direction L3 by the distance LN″, than to directly beneath the interface of the gate electrode 13 on the source electrode 11″ side than in the case where the interface of the p⁺-type contact layer 10 on the drain electrode 5″ side, which is directly beneath the n⁺-type source layer 9″, is formed up to directly beneath the interface of the gate electrode 13 on the source electrode 11″ side. This is because a larger amount of electron current flows through the interface of the p⁺-type contact layer 10 on the collector-drain electrode 5′ side, which is directly beneath the n⁺-type source layer 9″, from the n⁺-type source layer 9″ to the n⁻-type extended drain layer 2 via the p-type base layer 8 directly beneath the gate oxide film 12, in the case where the interface of the p⁺-type contact layer 10 on the drain electrode 5″ side, which is directly beneath the n⁺-type source layer 9″, is formed at a position closer to the source electrode 11″ side, in the direction L3 by the distance LN″, than to directly beneath the interface of the gate electrode 13 on the source electrode 11″ side than in the case where interface of the p⁺-type contact layer 10 on the collector-drain electrode 5′ side, which is directly beneath the n⁺-type source layer 9″, is formed up to directly beneath the interface of the gate electrode 13 on the source electrode 11″ side.

Thus, as in the case of the semiconductor device according to the first embodiment, it is preferable that the distance LN″ be 0.5 μm<LN″<1.5 μm in the case where the interface of the p⁺-type contact layer 10 on the drain electrode 5″ side, which is directly beneath the n⁺-type source layer 9″, is formed at a position closer to the source electrode 11″ side, in the direction L3 by the distance LN″, than to directly beneath the interface of the gate electrode 13 on the source electrode 11″ side.

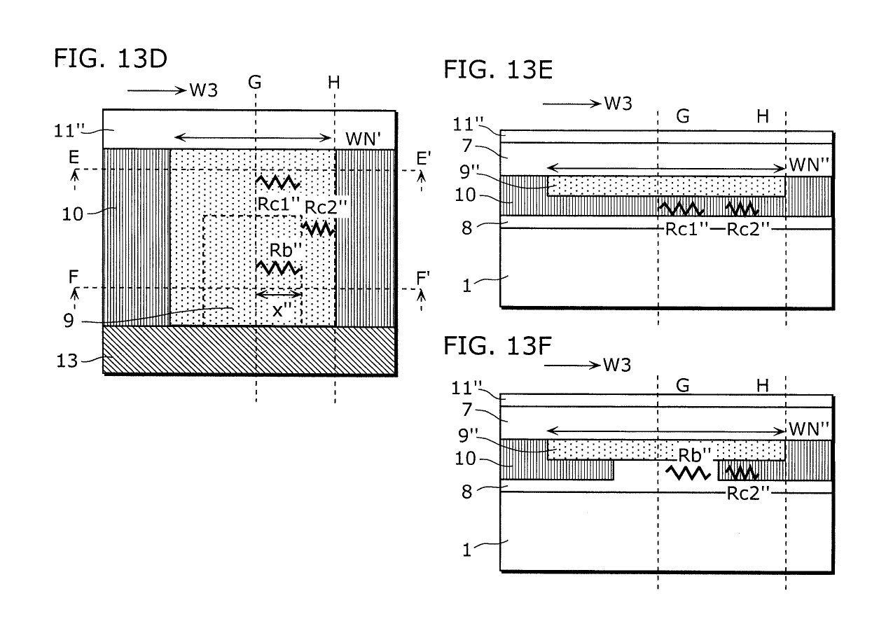

Furthermore, a resistance RP″ in the third vertical direction of the p-type base layer 8 and the p⁺-type contact layer 10 that are directly beneath the n⁺-type source layer 9″ is described. FIG. 13D is a plan view enlarging a region surrounded by a dotted line D in FIG. 12A. In addition, FIGS. 13E and 13F show cross-sectional views taken along with line E-E′ and F-F′ in FIG. 12D.

The following faces are considered: a center face G in the third vertical direction of the n⁺-type source layer 9″ made up of reed-shaped portions and a length WN″ in the third vertical direction, and an edge face H in the third vertical direction of the n⁺-type source layer 9″. At this time, when holes that are present in the center face G and directly beneath the n⁺-type source layer 9″ move to the edge face H directly beneath the n⁺-type source layer 9″, the holes are influenced by three resistances shown below.

1. Resistance Rb″ of the p-type base layer 8, which is generated when the holes move from the center face G in the third vertical direction by a length X″

2. Resistance Rc1″ of the p⁺-type contact layer 10, which is generated when the holes move from the center face G in the third vertical direction by the length X″

3. Resistance Rc2″ of the p⁺-type contact layer 10, which is generated when the holes move, to the edge face H, from a point distant from the center face G in the third vertical direction by the length X″

RP″ is a combined resistance of these three resistances, and is represented by the expression below.

RP″=(1/Rb″+1/Rc1″)⁻¹+Rc2″

Considering the combined resistance RP″ in the third vertical direction of the p-type base layer 8 and the P⁺-type contact layer 10 that are directly beneath the n⁺-type source layer 9″, it is preferable that RP″ be 7Ω<RP″<200Ω as in the case of the semiconductor device according to the first embodiment. By setting to 7Ω<RP<200Ω, the combined resistance RP″ of the p-type base layer 8 and p⁺-type contact layer 10 that are present directly beneath the n⁺-type source layer 9″, the latchup current can be 100 A/cm² or more without causing an increase in ON-resistance. Specifically, in time of avalanche destruction, it is possible to satisfy: current flowing in the source>100 A/cm2 or above.

Thus, when setting to 7Ω<RP″<200Ω, the combined resistance RP″ of the p-type base layer 8 and p⁺-type contact layer 10 that are present directly beneath the n⁺-type source layer 9″, it is preferable that the length WN″ in the third vertical direction of the n⁺-type source layer 9″ be 0.3 μm<WN″<2.0 μm. Thus, the combined resistance RP″ can be 7Ω<RP″<200Ω without changing the process of injection into the n-type source layer and the p⁺-type contact layer.

(Variation 1)

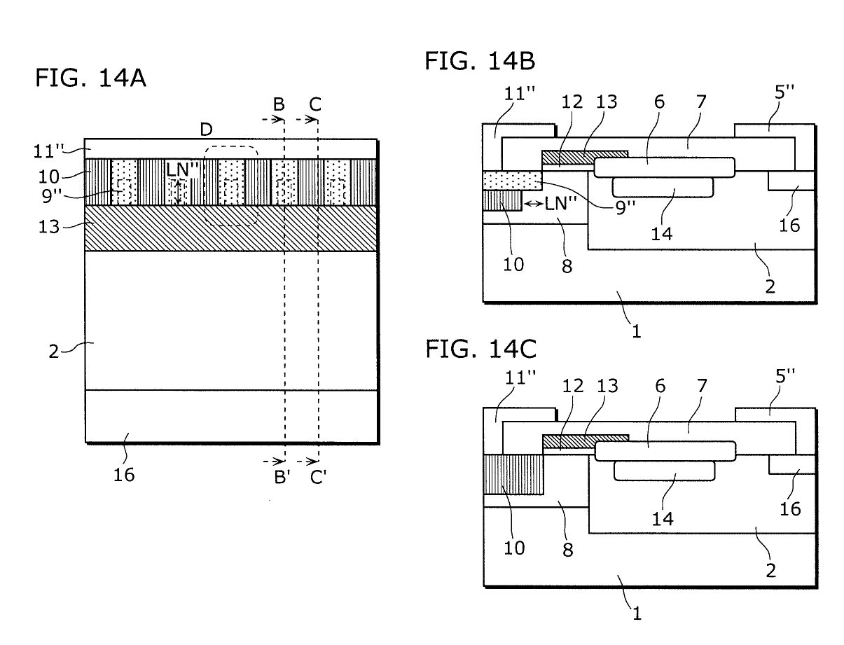

Hereinafter, a semiconductor device according to a first variation of the third embodiment is described with reference to FIG. 14. FIG. 14A is a plan view showing a structure of the semiconductor device according to the first variation of the third embodiment of the present invention. FIGS. 14B and 14C are cross-sectional views showing the structure of the semiconductor device according to the first variation of the third embodiment of the present invention, and show, respectively, cross-sectional views taken along with line B-B′ and line C-C′ in FIG. 14A. Note that in FIG. 14A, part of the constituent elements are not illustrated. The semiconductor device according to the first variation is specifically described in terms of differences from the semiconductor device according to the third embodiment.

As shown in FIGS. 14B and 14C, the semiconductor device according to the first variation has, in a surface portion of the n⁻-type extended drain layer 2, a p-type top semiconductor layer 14 which is equivalent to the p-type base layer 8 in terms of electrical potential.

With the semiconductor device according to the present variation, by providing the p-type top semiconductor layer 14 as above, a depletion layer is likely to expand within the n⁻-type extended drain layer 2 at the time of reverse bias, thus allowing highly-concentrated impurities to be contained in the n⁻-type extended drain layer 2 while maintaining a high withstand voltage at the same time, so that it becomes possible to increase ON-current.

(Variation 2)

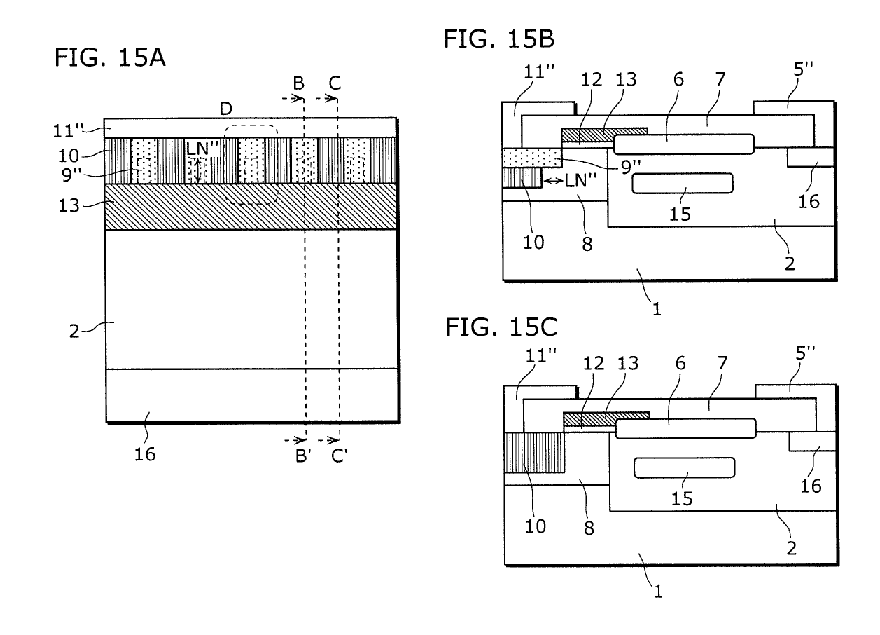

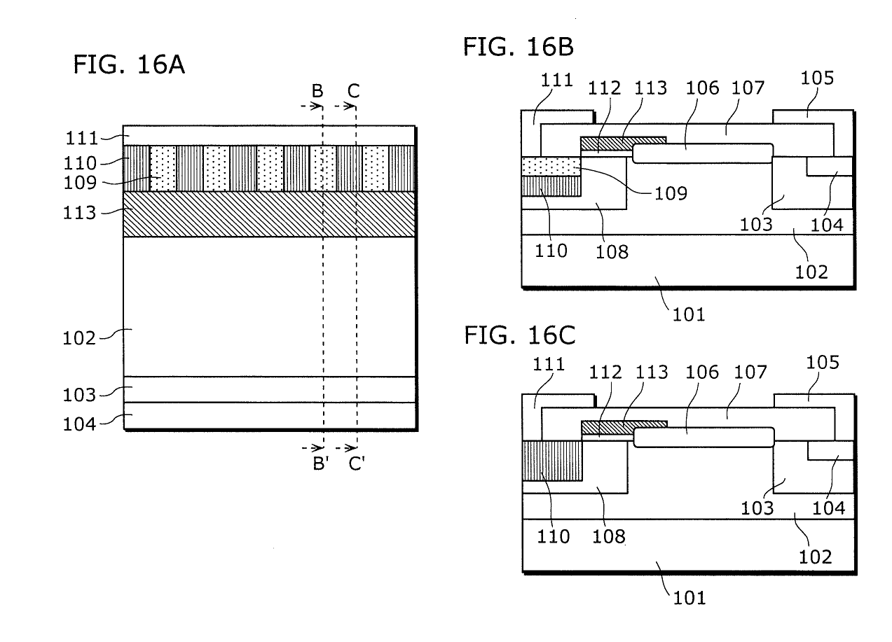

Hereinafter, a semiconductor device according to a second variation of the third embodiment is described with reference to FIG. 15. FIG. 15A is a plan view showing a structure of the semiconductor device according to the second variation of the third embodiment of the present invention. FIGS. 15B and 15C are cross-sectional views showing the structure of the semiconductor device according to the second variation of the third embodiment of the present invention, and show, respectively, cross-sectional views taken along with line B-B′ and line C-C′ in FIG. 15A. Note that in FIG. 15A, part of the constituent elements are not illustrated. The semiconductor device according to the first variation is specifically described in terms of differences from the semiconductor device according to the first embodiment.

As shown in FIGS. 15B and 15C, the semiconductor device according to the second variation includes, inside the n-type extended drain layer 2, a p-type buried semiconductor layer 15 which is equivalent to the p-type base layer 8 in terms of electrical potential.

With the semiconductor device according to the present variation, by thus providing the p-type top semiconductor layer 14, a depletion layer is likely to expand within the n⁻-type extended drain layer 2 at the time of reverse bias, thus allowing highly-concentrated impurities to be contained in the n⁻-type extended drain layer 2 while maintaining a high withstand voltage at the same time, so that it becomes possible to increase ON-current.

Although only some exemplary embodiments of the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

### INDUSTRIAL APPLICABILITY

The semiconductor device according to the present invention can increase latchup current without increasing ON-resistance, and is therefore effective for a semiconductor device such as a lateral insulated gate bipolar transistor having a high withstand voltage, which is used for a switching power supply.

What is claimed is:

1. A semiconductor device, comprising:
a semiconductor substrate of a first conductivity type;
an extended drain layer of a second conductivity type, which is formed on a surface of said semiconductor substrate;
a collector layer of the first conductivity type, which is formed on a surface of said extended drain layer;
a collector electrode electrically connected to said collector layer;
a base layer of the first conductivity type, which is formed at a distance from said collector layer;
an emitter layer of the second conductivity type, which is made up of reed-shaped portions discretely formed on a surface of said base layer;
a contact layer of the first conductivity type, which is formed from the surface of said base layer down to a region deeper than said emitter layer;
an emitter electrode which electrically connects said emitter layer and said contact layer; and
a gate electrode connected to the surface of said base layer via a gate oxide film,
wherein the reed-shaped portions of said emitter layer are discretely formed in a first vertical direction that is a direction vertical to a direction from said emitter electrode to said collector electrode,
a first part of an interface of said contact layer is formed up to directly beneath an interface of said gate electrode on a side of said emitter electrode, the first part being on a side of said collector electrode and in a region adjoining said emitter layer, and
a second part of the interface of said contact layer is formed closer to said emitter electrode than to the interface of said gate electrode on the side of said emitter electrode, the second part being on the side of said collector electrode and directly beneath said emitter layer.

2. The semiconductor device according to claim 1,
wherein 0.5 μm<LN<1.5 μm is satisfied where LN is a distance from the second part to directly beneath a gate.

3. The semiconductor device according to claim 1,
wherein 7Ω<RP<200Ω is satisfied where RP is a resistance in the first vertical direction defined by said base layer and said contact layer that are present directly beneath said emitter layer.

4. The semiconductor device according to claim 1,
wherein 0.3 μm<WN<2.0 μm is satisfied where WN is a length in the first vertical direction of said emitter layer.

5. The semiconductor device according to claim 1, further comprising a top semiconductor layer of the first conductivity type in a surface portion of said extended drain layer.

6. The semiconductor device according to claim 1,
wherein said extended drain layer includes a buried semiconductor layer of the first conductivity type.

7. A semiconductor device, comprising:
a semiconductor substrate of a first conductivity type;
an extended drain layer of a second conductivity type, which is formed on a surface of said semiconductor substrate;
a collector layer of the first conductivity type, which is formed on a surface of said extended drain layer;
a drain layer of the second conductivity type, which is formed on the surface of said extended drain layer;
a collector-drain electrode electrically connected to said collector layer and said drain layer;
a base layer of the first conductivity type, which is formed at a distance from said collector layer and said drain layer;
an emitter-source layer of the second conductivity type, which is made up of reed-shaped portions discretely formed on a surface of said base layer;
a contact layer of the first conductivity type, which is formed from the surface of said base layer down to a region deeper than said emitter-source layer;
an emitter-source electrode which electrically connects said emitter-source layer and said contact layer; and
a gate electrode connected to the surface of said base layer via a gate oxide film,
wherein the reed-shaped portions of said emitter-source layer are discretely formed in a second vertical direction that is a direction vertical to a direction from said emitter-source electrode to said collector-drain electrode,
a first part of an interface of said contact layer is formed up to directly beneath an interface of said gate electrode on a side of said emitter-source electrode, the first part being on a side of said collector-drain electrode and in a region adjoining said emitter-source layer, and
a second part of the interface of said contact layer is formed closer to said emitter-source electrode than to the interface of said gate electrode on the side of said emitter-source electrode, the second part being on the side of said collector-drain electrode and directly beneath said emitter-source layer.

8. The semiconductor device according to claim 7,
wherein 0.5 μm<LN′<1.5 μm is satisfied where LN′ is a distance from the second part to directly beneath a gate.

9. The semiconductor device according to claim 7,
wherein 7Ω<RP′<200Ω is satisfied where RP′ is a resistance in the second vertical direction defined by said base layer and said contact layer that are present directly beneath said emitter-source layer.

10. The semiconductor device according to claim 7,
wherein 0.3 μm<WN′<2.0 μm is satisfied where WN′ is a length in the second vertical direction of said emitter-source layer.

11. The semiconductor device according to claim 7, further comprising a top semiconductor layer of the first conductivity type in a surface portion of said extended drain layer.

12. The semiconductor device according to claim 7,
wherein said extended drain layer includes a buried semiconductor layer of the first conductivity type.

13. A semiconductor device, comprising:
a semiconductor substrate of a first conductivity type;
an extended drain layer of a second conductivity type, which is formed on a surface of said semiconductor substrate;
a drain layer of the second conductivity type, which is formed on a surface of said extended drain layer;
a drain electrode electrically connected to said drain layer;
a base layer of the first conductivity type, which is formed at a distance from said drain layer;
a source layer of the second conductivity type, which is made up of reed-shaped portions discretely formed on a surface of said base layer;
a contact layer of the first conductivity type, which is formed from the surface of said base layer down to a region deeper than said source layer;
a source electrode which electrically connects said source layer and said contact layer; and
a gate electrode connected to the surface of said base layer via a gate oxide film,
wherein the reed-shaped portions of said source layer are discretely formed in a third vertical direction that is a direction vertical to a direction from said source electrode to said drain electrode,
a first part of an interface of said contact layer is formed up to directly beneath an interface of said gate electrode on a side of said source electrode, the first part being on a side of said drain electrode and in a region adjoining said source layer, and
a second part of the interface of said contact layer is formed closer to said source electrode than to the interface of said gate electrode on the side of said source electrode, the second part being on the side of said drain electrode and directly beneath said source layer.

14. The semiconductor device according to claim 13,
wherein 0.5 μm<LN″<1.5 μm is satisfied where LN″ is a distance from the second part to directly beneath a gate.

15. The semiconductor device according to claim 13,
wherein 7Ω<RP″<200Ω is satisfied where RP″ is a resistance in the third vertical direction defined by said base layer and said contact layer that are present directly beneath said source layer.

16. The semiconductor device according to claim 13,
wherein 0.3 μm<WN″<2.0 μm is satisfied where WN″ is a length in the third vertical direction of said source layer.

17. The semiconductor device according to claim 13, further comprising a top semiconductor layer of the first conductivity type in a surface portion of said extended drain layer.

18. The semiconductor device according to claim 13,
wherein said extended drain layer includes a buried semiconductor layer of the first conductivity type.
